(19) United States
(12) Patent Application Publication
(10) Pub. No.: US 2022/0013813 A1
(43) Pub. Date: Jan. 13, 2022

(54) APPARATUS FOR MINING BATTERY CHARACTERISTIC DATA HAVING SENSITIVITY TO VOLUME FRACTION OF ACTIVE MATERIAL OF BATTERY ELECTRODE AND METHOD THEREOF

(71) Applicant: LG ENERGY SOLUTION, LTD., Seoul (KR)

(72) Inventors: Geum-Bee KIM, Daejeon (KR); Qingzhi LAI, Davis, CA (US); Xinfan LIN, Davis, CA (US); Hyoung Jun AHN, Daejeon (KR); Won-Tae JOE, Daejeon (KR)

(73) Assignee: LG ENERGY SOLUTION, LTD., Seoul (KR)

(21) Appl. No.: 17/370,394

(22) Filed: Sep. 20, 2021

(30) Foreign Application Priority Data
Jul. 9, 2020 (KR) 10-2020-0084988

(51) Int. Cl. H01M 10/42; H01M 10/48

(52) U.S. Cl. CPC H01M 10/425; H01M 2220/20; H01M 2010/4271; H01M 10/486

(57) ABSTRACT

Disclosed is an apparatus and method for mining battery characteristic data, which calculates a particle surface concentration (c_{se,i}) of lithium from a first state space model derived from a Pade approximation equation of a transcendental transfer function, calculates a change ratio

$$\frac{\partial {c}_{se , i}}{\partial \text{?}} ( t )$$

$$\text{?} \text{indicates text missing or illegible when filed}$$

of the particle surface concentration to the change in the active material volume fraction from a second state space model derived by the partial derivative of the Pade approximation equation, calculates a change ratio

$$\frac{\partial {η}_{i} ( t )}{\partial ɛ \text{?}}$$

$$\text{?} \text{indicates text missing or illegible when filed}$$

of over-potential to the change in the active material volume fraction from the Butler-Vollmer equation, calculates a potential slope

$$\frac{\partial {U}_{i}}{\partial {c}_{se , i}}$$

corresponding to the particle surface concentration by using an open circuit potential function, and stores voltage-current data in which the sensitivity of the battery voltage to the active material volume fraction of the electrode calculated from

$$\frac{\partial {U}_{i}}{\partial {c}_{se , i}} , \frac{\partial {c}_{se , i}}{\partial {ɛ}_{s , i}} ( t ) and \frac{\partial {η}_{i} ( t )}{\partial {ɛ}_{s , i}}$$

is greater than or equal to a threshold as mined characteristic data.

### TECHNICAL FIELD

The present application claims priority to Korean Patent Application No. 10-2020-0084988 filed on Jul. 9, 2020 in the Republic of Korea, the disclosures of which are incorporated herein by reference.

The present disclosure relates to an apparatus and method for mining battery characteristic data having sensitivity to electrochemical parameters of a battery.

### BACKGROUND ART

State and parameter estimation is one of the most important topics in battery management/control. Offline battery parameterization is needed to generate a model with adequate fidelity for control.

On the other hand, online estimation of key battery states and parameters, e.g. state of charge (SOC), state of health (SOH), and state of power (SOP), is critical for monitoring and maintaining battery performance in real time.

Three basic elements are involved in the process of estimation, namely model, algorithm and data. The algorithm fits the measurement data, e.g. battery current and voltage, to the model to produce the estimates of the state and parameters.

Traditionally, the research in this area is dominated by developing models and algorithms. The models researched include equivalent circuit model (ECM), pseudo-2D model (P2D), the simplified single particle model (SPM), and the like. The algorithms researched include Kalman Filter, Bayesian estimator, Particle Filter, Lyapunov-based approach for estimation, and the like.

However, the importance of data in estimation of state and parameter has long been neglected. It is found that the sensitivity of the input and output data to the target variable determines the accuracy of estimation to a large extent. For example, the estimation error variance and bias induced by measurement noises and model uncertainty will be suppressed by sensitive data and amplified by insensitive ones. Nevertheless, most existing estimation practices do not consider data sensitivity and optimize the data used for estimation.

For offline parameterization, empirically determined current excitations, such as constant-current charging/discharging and pulse profiles, are predominantly used. Meanwhile, for online estimation, most algorithms simply use all the data points from random online data stream to estimate every single target variable. However, it is often the case that the empirical test profiles are only sensitive to a small portion of the model parameters subject to identification, and only a small fraction data from the random online data stream are sensitive to the target variables subject to real-time estimation. Lack of sensitive data is one of the major causes for inaccurate and unreliable estimation results. This is a fundamental limit imposed by data which cannot be addressed by model or algorithm improvement.

Recently, studies on sensitivity analysis and data optimization have received increasing attention. Some early works focused on numerically calculating the sensitivity of battery states and parameters to existing test data and determine the sensitive ones that are robustly identifiable.

Some later ones devoted to designing optimal current profile, which optimizes the sensitivity or sensitivity-related metrics of model parameters, e.g. Fisher information matrix and Cramer-Rao bound, for offline and online system identification.

More interestingly, a recent work proposed a data selection/mining scheme for real-time estimation. The corresponding work aims at identifying sensitive data points/segments from random online stream and uses them exclusively for estimation of battery states and parameters. These works have demonstrated promising results in guaranteeing and improving the quality of battery state and parameter estimation.

Although significant progress has been made, there are still major challenges remaining to be addressed. So far, most results regarding data optimization for offline and online estimation are limited to the equivalent circuit model, which is a phenomenological model capturing the macroscopic dynamics of the battery.

The new trend in battery research is the increasing adoption of electrochemical models, e.g. the P2D and SPM. They have been considered as the future solution for battery estimation and control due to their high fidelity and capability of capturing underlying battery physics. For these models, however, most existing studies are limited to numerical sensitivity calculation and sensitive variable screening under existing test data. That is, there is not much progress in data optimization for estimation.

Recent researches have made an important contribution to formulate an optimal experiment design problem. In the corresponding researches, miscellaneous current profiles, including pulses, sine waves, and drive cycles, are chosen from a pre-established library and combined to maximize the Fisher information of the parameters of a P2D model. Nevertheless, the result is only optimal within the empirically determined input library but not necessarily the ultimate best current profile.

The main obstacle facing the data optimization for electrochemical model-based estimation is the complexity of sensitivity calculation. The common method is to solve the sensitivity differential equations (SDEs), which is obtained by taking the partial derivative of the original model equations to the target variables.

Due to the lack of analytic solution, SDEs are typically solved through numerical simulation together with the original model equations. Consequently, the computational load is intractable for optimization, since most algorithms need to solve the equations iteratively over a large search space to find the optimum. The computational complexity also poses great challenge for data selection/mining for real-time estimation. This is because real-time estimation is subject to stringent constraint on computational power and time.

### DISCLOSURE

### Technical Problem

The present disclosure is designed to solve the problems of the related art, and therefore the present disclosure is directed to providing an apparatus and method for mining battery characteristic data, which may improve the reliability and accuracy of the estimation of electrochemical parameters by deriving an analytic expression for an active material volume fraction of an electrode, which is one of electrochemical parameters of a battery, and quantifying the sensitivity of the electrochemical parameters for the measurement data on the electrochemical properties of the battery.

### Technical Solution

In one aspect of the present disclosure, there is provided an apparatus for mining battery characteristic data having sensitivity to an active material volume fraction of a battery electrode, comprising: a storage unit configured to store data; a voltage measuring unit, a current measuring unit and a temperature measuring unit respectively configured to measure voltage, current and temperature of a battery; and a control unit operably coupled to the storage unit as well as the voltage measuring unit, the current measuring unit and the temperature measuring unit.

Preferably, the control unit may be configured to: (a) generate a Pade approximation equation for a transcendental transfer function from a battery current to a particle surface concentration of lithium inserted into the electrode in a frequency domain; (b) generate a first state space model for the Pade approximation equation and a second state space model for partial derivative of an active material volume fraction of the electrode with respect to the Pade approximation equation; (c) obtain a data stream including a voltage measurement value, a current measurement value and a temperature measurement value of the battery; (d) calculate a change ratio of over-potential to the change in the active material volume fraction by inputting the current measurement value and the temperature measurement value to the partial derivative of the active material volume fraction for an over-potential equation derived from the Butler-Vollmer equation; (e) input the current measurement value into the first state space model to calculate the particle surface concentration of lithium inserted into the electrode; (f) input the current measurement value into the second state space model to calculate a change ratio of the particle surface concentration to the change in the active material volume fraction; (g) calculate an open circuit potential slope corresponding to the calculated particle surface concentration by using a predefined open circuit potential function according to the particle surface concentration; (h) quantitatively estimate the sensitivity of a battery voltage for the active material volume fraction of the electrode from the change ratio of the over-potential to the change in the active material volume fraction, the open circuit potential slope, and the change ratio of the particle surface concentration to the change in the active material volume fraction; and (i) select voltage-current data having sensitivity greater than or equal to a threshold and recording the same as mined characteristic data in the storage unit.

In another aspect of the present disclosure, there is also provided a method for mining battery characteristic data having sensitivity to an active material volume fraction of a battery electrode, comprising: (a) generating a Pade approximation equation for a transcendental transfer function from a battery current to a particle surface concentration of lithium inserted into the electrode in a frequency domain; (b) generating a first state space model for the Pade approximation equation and a second state space model for partial derivative of an active material volume fraction of the electrode with respect to the Pade approximation equation; (c) obtaining a data stream including a voltage measurement value, a current measurement value and a temperature measurement value of the battery; (d) calculating a change ratio of over-potential to the change in the active material volume fraction by inputting the current measurement value and the temperature measurement value to the partial derivative of the active material volume fraction for an over-potential equation derived from the Butler-Vollmer equation; (e) inputting the current measurement value into the first state space model to calculate the particle surface concentration of lithium inserted into the electrode; (f) inputting the current measurement value into the second state space model to calculate a change ratio of the particle surface concentration to the change in the active material volume fraction; (g) calculating an open circuit potential slope corresponding to the calculated particle surface concentration by using a predefined open circuit potential function according to the particle surface concentration; (h) quantitatively estimating the sensitivity of a battery voltage for the active material volume fraction of the electrode from the change ratio of the over-potential to the change in the active material volume fraction, the open circuit potential slope, and the change ratio of the particle surface concentration to the change in the active material volume fraction; and (i) selecting voltage-current data having sensitivity greater than or equal to a threshold and recording the same as mined characteristic data in a storage unit.

In another aspect of the present disclosure, there is also provided a battery management system and an electric driving mechanism, which comprises the apparatus for mining battery characteristic data having sensitivity to an active material volume fraction of a battery electrode.

### Advantageous Effects

The present disclosure provides an analytic expression for the sensitivity to an active material volume fraction of an electrode, which is one of battery electrochemical parameters. The analytic expression will enable theoretic sensitivity analysis, tractable offline optimization, and efficient online computation.

The contributions of the present disclosure are three-folds. First, in the present disclosure, an analytic expression capable of quantitatively estimating the sensitivity to an active material volume fraction εₛ of an electrode, which is one of important battery electrochemical parameters, will be derived. The active material volume fraction εₛ is a volume fraction of an active material with activity in the electrode. The active material volume fraction εₛ is a parameter that gradually decreases as the battery is degraded.

The derivation of the analytic expression is based on a single particle model (SPM). The single particle model is a popular control-oriented simplification of the full order P2D model. In the present disclosure, the Laplace-domain approach will be used. The Laplace-domain approach facilitates the (otherwise infeasible) analytic derivation of dynamic sensitivity. The methodology may also be applied to generic electrochemical parameters.

Second, in-depth understanding on the features of sensitive data is obtained by examining the derived expressions. Specifically, the analytic results reveal the frequency spectrum and bandwidth of sensitive data, and the decomposition of sensitivity into linear/nonlinear and static/dynamic parts.

Third, the derived sensitivity based on the SPM is compared with the numerical simulation of a P2D model for verification. It is shown that the SPM-based sensitivity matches reasonably well with that of the P2D model, demonstrating the potential of using the derived analytic expressions for sensitivity analysis of P2D model and data optimization.

### DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a conceptual diagram schematically showing a single particle model (SPM) according to an embodiment of the present disclosure.

FIG. 2 is the Bode plot of a normalized sensitivity transfer function for an active material volume fraction ε_{s,p} of a positive electrode.

FIG. 3 is a graph showing a comparison result of normalized

$$\frac{\partial η}{\partial {ɛ}_{s , p}} \cdot {ɛ}_{s , p}$$

for a positive electrode under constant-current discharging. Here, a solid line denotes the sensitivity using the numerical simulation from the P2D, and a dotted line denotes the sensitivity using the analytic derivation from the SPM.

FIG. 4 is a graph showing a comparison result of normalized

$$\frac{\partial {c}_{se}}{\partial {ɛ}_{s , p}} \cdot {ɛ}_{s , p}$$

for a positive electrode under constant-current discharging. Here, a solid line denotes the sensitivity using the numerical simulation from the P2D, and a dotted line denotes the sensitivity using the analytic derivation from the SPM.

FIG. 5 is a graph showing a comparison result of normalized

$$\frac{\partial V}{\partial {ɛ}_{s , p}} \cdot {ɛ}_{s , p}$$

for a positive electrode under constant-current discharging. Here, a solid line denotes the sensitivity using the numerical simulation from the P2D, and a dotted line denotes the sensitivity using the analytic derivation from the SPM.

FIG. 6 is a graph showing a comparison result of normalized

$$\frac{\partial V}{\partial {ɛ}_{s , p}} \cdot {ɛ}_{s , p}$$

for a positive electrode under a pulse current. Here, a solid line denotes the sensitivity using the numerical simulation from the P2D, and a dotted line denotes the sensitivity using the analytic derivation from the SPM.

FIG. 7 is a block diagram schematically showing an apparatus for mining battery characteristic data having sensitivity to an active material volume fraction of a battery electrode according to an embodiment of the present disclosure.

FIGS. 8 and 9 are flowcharts for illustrating a method of mining battery characteristic data having sensitivity to an active material volume fraction of a battery electrode according to an embodiment of the present disclosure.

### BEST MODE

Hereinafter, preferred embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation. Therefore, the description proposed herein is just a preferable example for the purpose of illustrations only, not intended to limit the scope of the disclosure, so it should be understood that other equivalents and modifications could be made thereto without departing from the scope of the disclosure.

In the embodiments described below, a battery refers to a lithium secondary battery such as a lithium polymer battery. Here, the lithium secondary battery collectively refers to a secondary battery in which lithium ions act as operating ions during charging and discharging to cause an electrochemical reaction at a positive electrode and a negative electrode.

Meanwhile, even if the name of the secondary battery changes depending on the type of electrolyte or separator used in the lithium secondary battery, the type of packaging material used to package the secondary battery, and the interior or exterior structure of the lithium secondary battery, as long as lithium ions are used as operating ions, the secondary battery should be interpreted as being included in the category of the lithium secondary battery.

The present disclosure may also be applied to other secondary batteries other than the lithium secondary battery. Therefore, even if the operating ions are not lithium ions, any secondary battery to which the technical idea of the present disclosure may be applied should be interpreted as being included in the category of the present disclosure regardless of its type.

In addition, the battery may refer to one unit cell or a plurality of unit cells connected in series or in parallel.

First, various symbols used in an embodiment of the present disclosure are defined. If no definitions are given for symbols used in the equations of the present disclosure, the following definitions may be referred to.

### Definition of Symbols

cₛₑ: particle surface concentration of solid-phase particle into which lithium is inserted [mol·m⁻³]

cₑ: lithium concentration in an electrolyte [mol·m⁻³]

Φₛ: potential of solid-phase particle [V]

Φₑ: potential of an electrolyte [V]

Jᵢ^{Li}: lithium ion current density in an electrode [A·m⁻²]

i₀: exchange current density [A·m⁻²]

η: over-potential [V]

k: dynamic reaction rate [s⁻¹·mol^{-0.5}·m^{2.5}]

R: universal gas constant [J·mol⁻¹·K⁻¹]

F: Faraday constant [C·mol⁻¹]

T: temperature [K]

αₐ: charge transfer coefficient of a negative electrode [no units]

α_{c}: charge transfer coefficient of a positive electrode [no units]

c_{s,max}: maximum concentration of lithium in solid-phase particle [mol·m⁻³]

δ: thickness of a predetermined area [m]

I: battery current [A], where a charging current is negative and a discharging current is positive

V: terminal voltage of a battery [V]

A: effective electrode area [m²]

Vol: electrode volume [m⁻³]

Dₛ: solid-phase diffusion coefficient [m²·s⁻¹]

Dₑ: electrolyte diffusion coefficient [m²·s⁻¹]

aₛ: active surface area per electrode unit volume (m²·m⁻³, corresponding to 3*εₛ/Rₛ)

εₛ: volume fraction of active material with activity in an electrode [no units]

Rₛ: radius of solid-phase active material particle [m]

U: open circuit potential of solid-phase active material [V]

R_{f}: solid-electrolyte interphase film resistance [Ω·m²]

Rₗᵤₘₚ: lumped resistance of a battery [Ω·m²]

t₀⁺: Li ion transference [no units]

subscript eff: effective

subscript s: solid-phase

subscript e: electrolyte-phase

subscript p: positive electrode

subscript n: negative electrode

Single Particle Model

In an embodiment of the present disclosure, electrochemical battery models capture the electrochemical reactions and processes occurring inside the battery during operation.

In the P2D model well known in the art, the electrochemical dynamics are captured by 4 coupled partial differential equations (PDE) and 1 Butler Vollmer Equation.

Due to the computational complexity of solving the coupled PDE system, many researchers have sought to develop reduced-order model (ROM) based on certain assumptions.

The most widely used ROM is the single particle model (SPM). The single particle model assumes that the current density across the battery electrode is uniform. Based on this assumption, one single particle is used to represent the whole electrode. Consequently, in the SPM, various dynamics are decoupled to facilitate the solution of the coupled PDEs. The simplified structure of the SPM also makes it possible to analytically derive the sensitivity of battery electrochemical parameters, which is the focus of the present disclosure.

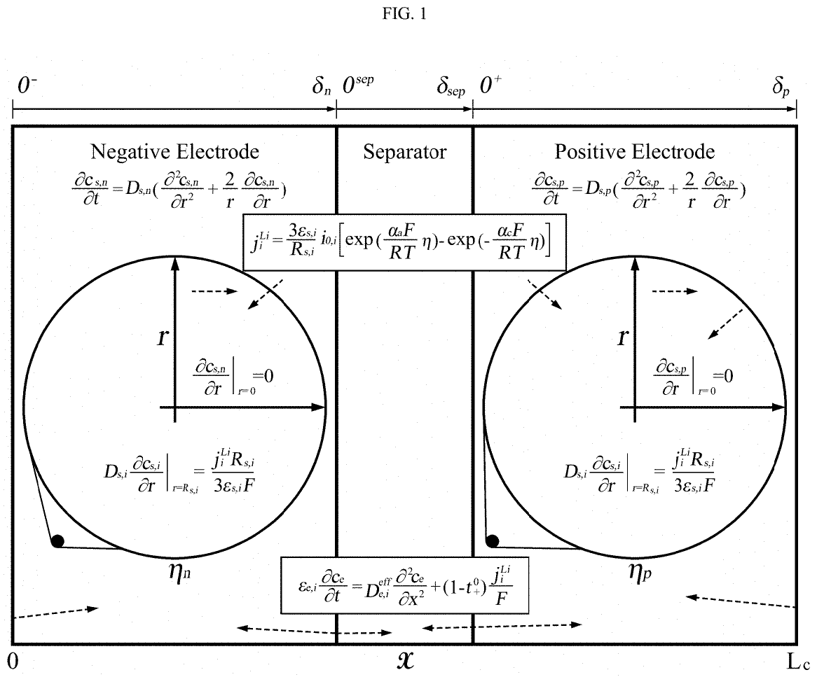

FIG. 1 is a conceptual diagram schematically showing a single particle model (SPM) according to the present disclosure.

First, a SPM, which consists of sub-models capturing solid-phase lithium diffusion, liquid-phase lithium diffusion, lithium (de)intercalation and the voltage output, will be described with reference to FIG. 1.

Solid-Phase Diffusion

The diffusion of lithium in the electrode particle is governed by the Fick's Law of Equation (1) in the spherical coordinate. In the electrode particle, boundary conditions for the diffusion of lithium may be expressed as in Equations (2) and (3). The boundary conditions capture the variation of solid-phase lithium concentration over time and space along the particle radius direction (r). The symbol i denotes the type of electrode. If the symbol i is p, this denotes a positive electrode, and if the symbol i is n, this denotes a negative electrode.

$$\begin{matrix}\frac{\partial {c}_{s , i}}{\partial t} {D}_{s , i} ( \frac{{\partial }^{2} {c}_{s , i}}{\partial {r}^{2}} + \frac{2}{r} \frac{\partial {c}_{s , i}}{\partial r} ) & ( 1 ) \\ \frac{\partial {c}_{s , i}}{\partial r} {\vert}_{r = 0} = 0 & ( 2 ) \\ {D}_{s , i} \frac{\partial {c}_{s , i}}{\partial r} {\vert}_{r = {R}_{s , i}} = \frac{{J}_{i}^{Li} {R}_{s , i}}{3 {ɛ}_{s , i} F} & ( 3 )\end{matrix}$$

D_{s,i}: solid-phase diffusion coefficient (m²·s⁻¹) of lithium, c_{s,i}: solid-phase concentration (mol·m⁻³) of lithium, R_{s,i}: electrode particle radius (m), ε_{s,i}: volume fraction (no units) of active material with activity in an electrode, F: Faraday constant (C/mol), r: variable of a spherical coordinate

In SPM, the current density Jᵢ^{Li} in Equation (3) is assumed as uniform across the electrode, and hence it may be calculated as the total current I divided by the electrode volume as in Equation (4) below.

$${J}_{i}^{Li} = \frac{I}{A {δ}_{i}} \qquad ( 4 )$$

Jᵢ^{Li}: lithium ion current density (A·m⁻²) in an electrode, A: electrode area (m²), δᵢ: electrode thickness (m)

Preferably, the PDE in Equation (1) needs to be discretized before it can be solved. In an embodiment of the present disclosure, Laplace transformation and Pade approximation are used for discretization.

Pade approximation is an approximation theory that approximates a function using a rational function of a given order. That is, Pade approximation approximates a given function as a rational function with an n^{th}-order polynomial as a denominator and an m^{th}-order polynomial as a numerator.

Specifically, for discretization of Equation (1), Laplace transformation of Equation (1) gives Equation (5).

$${D}_{s , i} \frac{{\partial }^{2} {C}_{s , i} ( s )}{\partial {r}^{2}} + \frac{2 {D}_{s , i}}{r} \frac{\partial {C}_{s , i} ( s )}{\partial r} - {sC}_{s , i} ( s ) = 0 \qquad ( 5 )$$

Then, by matching the boundary conditions in Equations (2) and (3), the transcendental transfer function from input current I to the lithium concentration c_{se,i} at the particle surface may be obtained as in Equation (6).

$$\frac{{C}_{se , i}}{I} ( s ) = - \frac{( {e}^{2 {R}_{s , i} \sqrt{s / {D}_{s , i}}} - 1 ) \frac{{R}_{s , i}^{2}}{3 A {δ}_{i} F {ɛ}_{s , i} {D}_{s , i}}}{1 + {R}_{s , i} \sqrt{\frac{s}{{D}_{s , i}}} + {e}^{2 {R}_{s , i} \sqrt{s / {D}_{s , i}}} ( {R}_{s , i} \sqrt{\frac{s}{{D}_{s , i}}} - 1 )} \qquad ( 6 )$$

C_{se,i}: particle surface concentration (mol·m⁻³) of lithium inserted into an electrode, I: battery current (A), R_{s,i}: radius (m) of electrode particle, D_{s,i}: solid-phase diffusion coefficient (m²·s⁻¹) of electrode particle, A: electrode area (m²), δᵢ: electrode thickness (m), F: Faraday constant (C/mol), ε_{s,i}: volume fraction (no units) of active material with activity in an electrode, s: Laplace transformation variable, e: natural constant

The transcendental transfer function expressed in Equation (6) cannot be solved directly in time domain. Therefore, a low-order rational transfer function is used for approximation based on moment matching.

At the end, a 3^{rd} order Pade approximation may be obtained for the lithium concentration c_{se,i} at the particle surface as in Equation (7).

$${c}_{se , i} ( s ) \approx - [ \frac{7 {R}_{s , i}^{4} {s}^{2} + 420 {D}_{s , i} {R}_{s , i}^{2} s + 3465 {D}_{s , i}^{2}}{F {ɛ}_{s , i} s ( {R}_{s , i}^{4} {s}^{2} + 189 {D}_{s , i} {R}_{s , i}^{2} s + 3465 {D}_{s , i}^{2} )} ] \cdot \frac{I ( s )}{A {δ}_{i}} \qquad ( 7 )$$

The Pade approximation for the lithium concentration c_{se,i} at the particle surface is disclosed in the paper ‘J. Marckcki, M. Cannova, A. T. Conlisk, and G. Rizzoni, “Design and parametrization analysis of a reduced-order electrochemical model of graphite/LiFePO₄ cells for SOC/SOH estimation”, Journal of Power Sources, vol. 237, pp. 310-324, 2013’ and the paper ‘J. C. Forman, S. Bashash, J. L. Stein, and H. K. Fathy, “Reduction of an Electrochemistry-Based Li-Ion Battery Model vis Quasi-Liniearization and Pade Approximation”, Journal of The Electrochemical Society, vol. 158, no. 2, p. A93, 2011’, the disclosures of which are incorporated herein by reference.

The Pade approximation equation may be converted into a first state space model in a canonical format in the time domain as shown in Equation (7)′ below.

$$[ \begin{matrix}{\dot{x}}_{1} \\ {\dot{x}}_{2} \\ {\dot{x}}_{3}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ - 1\end{matrix} ] I \\ y = {c}_{se , i} ( t ) = \frac{1}{F {ɛ}_{s , i} A {δ}_{i} {R}_{s , i}^{4}} [ \begin{matrix}3465 {D}_{s , i}^{2} & 420 {D}_{s , i} {R}_{s , i}^{2} & 7 {R}_{s , i}^{4} \end{matrix} ] [ \begin{matrix}{x}_{1} \\ {x}_{2} \\ {x}_{3}\end{matrix} ] \qquad {( 7 )}^{′}$$

In the first state space model, the input is a battery current and the output is a particle surface concentration c_{se,i} of lithium. Therefore, the first state space model may be used to capture the particle surface concentration c_{se,i} of lithium using the battery current I.

In the first state space model, initial conditions for x₁, x₂ and x₃ may be set using the initial SOC of the battery. That is, the initial conditions of x₂ and x₃ may be set to 0, and the initial conditions of x₁ may be determined such that c_{se,i} corresponding to the initial SOC is calculated as the output y of the first state space model.

The particle surface concentration c_{se,i} corresponding to the initial SOC may be determined through the following SOC-cₛₑ conversion equation.

$$SOC = \frac{β - {β}_{0 \%}}{{β}_{100 \%} - {β}_{0 \%}}$$

Here, β is c_{se,i}/c_{s,max,i}. That is, β is the ratio of the particle surface concentration to the maximum solid-phase concentration of lithium that may be included in the electrode particles. β_{0%} is a β value (stoichiometry) when the SOC is 0%, and β_{100%} is a β value (stoichiometry) when the SOC is 100%. c_{s,max,i}, β_{0%} and β_{100%} are known values predefined through experiments.

An embodiment of the present disclosure will use Equations (7) and (7)′ to derive the sensitivity of the battery voltage for the active material volume fraction ε_{s,i} with activity in an electrode. The sensitivity of the battery voltage to the active material volume fraction ε_{s,i} is defined as δV/δε_{s,i}, which is a factor that quantitatively indicates how much the battery voltage changes when the active material volume fraction ε_{s,i} is changed.

Liquid-Phase Lithium Diffusion

Lithium diffusion in electrolyte along the electrode thickness direction (x-direction in FIG. 1) is governed by the Fick's Law in Cartesian coordinate as expressed in Equation (8).

$${ɛ}_{e , i} \frac{\partial {c}_{e}}{\partial t} = {D}_{e , i}^{ef} \frac{{\partial }^{2} {c}_{e}}{\partial {x}^{2}} + ( 1 - {t}_{+}^{0} ) \frac{{j}_{i}^{Li}}{F} , ( 0 \leq x \leq {L}_{c} ) \qquad ( 8 )$$

cₑ: lithium concentration (mol·m⁻³) in electrolyte, ε_{e,i}: volume fraction of electrolyte (no units, corresponding to the porosity of the electrode), D_{e,i}^{eff}: effective electrolyte-phase diffusion coefficient (m²·s⁻¹), t₊⁰: Li ion transference, Lc: cell thickness (m), x: variable of the Cartesian coordinate.

Similar to the solid-phase diffusion, in the liquid-state lithium diffusion, Pade approximation may be applied to generate a low order rational transfer function and subsequently a state space model for the lithium concentration cₑ in the electrolyte.

However, the embodiment of the present disclosure relates to the calculation of sensitivity of the battery voltage for the active material volume fraction ε_{s,i} of the electrode, the liquid-phase lithium diffusion will not be described in detail.

Intercalation (Insertion) and Deintercalation (Removal) of Lithium

The intercalation (insertion) and deintercalation (removal) of lithium ion into and out of the electrode particle is driven by the over-potential ηᵢ at the particle surface as expressed in Equation (9).

$${η}_{i} = {ϕ}_{s , i} - {ϕ}_{e , i} - U ( {c}_{se , i} ) - {R}_{f} \frac{{j}_{i}^{Li}}{{a}_{s , i}} \qquad ( 9 )$$

ηᵢ: over-potential (V) of the electrode, Φᵢ: electrode potential (V), R_{f}: solid-electrolyte interphase film resistance (Ω·m²), a_{s,i}: active surface area per electrode unit volume (m²·m⁻³, corresponding to 3*ε_{s,i}/R_{s,i}), U: open circuit potential function, Jᵢ^{Li}: lithium ion current density (A·m⁻²) in the electrode.

The over-potential ηᵢ is the surplus of the electrode potential φ_{s,i} over the electrolyte potential φ_{e,i} and the open circuit potential U depending on the particle surface concentration c_{se,i}.

The lithium ion intercalation or deintercalation process is governed by the Butler-Vollmer equation as expressed in Equation (10) below.

$${j}_{i}^{Li} = \frac{3 {ɛ}_{s , i}}{{R}_{s , i}} {i}_{0 , i} [ exp ( \frac{{α}_{a} F}{RT} {η}_{i} ) - exp ( \frac{{α}_{c} F}{RT} {η}_{i} ) ] \qquad ( 10 )$$

Jᵢ^{Li}: current density (A·m⁻²) according to movement of lithium ion, ηᵢ: over-potential (V), i_{0,i}: exchange current density (A·m⁻²), R: universal gas constant (J·mol⁻¹·K⁻¹), T: battery temperature (K), αₐ and α_{c}: charge transfer coefficients (no units) of the negative electrode and the positive electrode, respectively.

In the SPM, since the current density is known from Equation (4), the over-potential ηᵢ in the negative electrode and the positive electrode may be calculated by inverting Equation (10) into Equation (11).

$${η}_{i} = \frac{RT}{α F} ln ( {ξ}_{i} + \sqrt{{ξ}_{i}^{2} + 1} ) \qquad ( 11 )$$

Here, ξᵢ may be expressed as Equation (12).

$${ξ}_{i} = \frac{{R}_{s , i} {j}_{i}^{Li}}{6 {ɛ}_{s , i} {i}_{0 , i}} \qquad ( 12 )$$

The over-potential ηᵢ calculated using Equation (11) may be used to calculate the battery voltage.

Battery Voltage

The output of the SPM is the battery voltage V. The voltage V may be calculated as the difference in the positive electrode potential and the negative electrode potential plus an additional voltage drop over a resistance (Re) of current collectors as in Equation (13).

As shown in FIG. 1, in Equation (13), x=0 is an x-coordinate of the negative electrode surface and L_{c} is an x-coordinate of the positive electrode surface.

V=ϕₛ(x=L_{c})−ϕs(x=0)−RₑI (13)

According to Equation (9), the positive electrode potential φ_{s,p} may be calculated using Equation (14).

$${ϕ}_{s , i} = {η}_{i} + {ϕ}_{e , i} + U ( {c}_{se , i} ) + {R}_{f} \frac{{j}_{i}^{Li}}{{a}_{s , i}} \qquad ( 14 )$$

Equation (15) for the voltage V may be obtained by combining Equation (13) and Equation (14).)

V=(Uₚ(c_{se,p})−Uₙ(c_{se,n}))+(ϕ_{e,p}−ϕ_{c,n})+(ηₚ−ηₙ)−RₗᵤₘₚI (15)

Here, Rₗᵤₘₚ is the lumped resistance, c_{se,i}, φ_{e,i} and ηᵢ may be computed from the previous sub-models. In the equation, p is a symbol indicating the positive electrode, and n is a symbol indicating the negative electrode.

Analytic Derivation of Parameter Sensitivity

In the present disclosure, the sensitivity of battery electrochemical parameters is derived based on the single particle model (SPM). Specifically, in this embodiment, analytic derivation for the active material volume fraction ε_{s,i} with activity in the electrode is provided.

The active material volume fraction ε_{s,i} is correlated with a_{s,i}, which is a parameter representing the active surface area per unit volume of the electrode. That is, a_{s,i} corresponds to 3*ε_{s,i}/R_{s,i}.

The active material volume fraction ε_{s,i} reflects critical battery electrochemical properties and is related to key performance indexes such as state of health (SOH) and state of power (SOP), and thus it has been of great interest for both offline and online estimation.

Therefore, the active material volume fraction ε_{s,i} is chosen as a target variable for sensitivity derivation. However, it is obvious that the present disclosure may be applied for deriving sensitivity of other parameters.

Sensitivity of Active Material Volume Fraction ε_{s,i}

The active material volume fraction ε_{s,i} affects the battery terminal voltage V through both the open circuit potential Uᵢ and the over-potential Therefore, the sensitivity of the active material volume fraction ε_{s,i} may be obtained by applying the chain rule of differentiation to Equation (15), and may be expressed as in Equation (16) below.

$$\frac{\partial V ( t )}{\partial {ɛ}_{s , i}} = \pm ( \frac{\partial {η}_{i} ( t )}{\partial {ɛ}_{s , i}} + \frac{\partial {U}_{i}}{\partial {c}_{se , i}} \cdot \frac{\partial {c}_{se , i} ( t )}{\partial {ɛ}_{s , i}} ) \qquad ( 16 )$$

Equation (16) consists of two terms. The first term,

$$\frac{\partial {η}_{i} ( t )}{\partial {ɛ}_{s , i}} ,$$

may be derived by applying the chain rule to Equation (11) and substituting Jᵢ^{Li} with I according to Equation (4), and may be expressed as in Equation (17) below.

$$\frac{\partial {η}_{i}}{\partial ɛ \text{?}} = \frac{\partial {η}_{i}}{\partial {ξ}_{i}} \text{?} ( \frac{\partial {ξ}_{i}}{\partial {ɛ}_{s , i}} ) = \frac{- RT}{α F {ɛ}_{s , i}} \text{?} \frac{sign ( I )}{\sqrt{1 + \frac{1}{{ξ}_{i}^{2}}}} = \frac{- RT}{α F {ɛ}_{s , i}} \cdot \frac{sign ( I )}{\sqrt{1 + {( \frac{6 {ɛ}_{s , i} \text{?} A {δ}_{i}}{{IR}_{s , i}} )}^{2}}} \\ \text{?} \text{indicates text missing or illegible when filed} \qquad ( 17 )$$

From Equation (17), it can be seen that

$$\frac{\partial {η}_{i} ( t )}{\partial {ɛ}_{s , i}}$$

is a nonlinear function of the input current I. The present disclosure refers to the first term as the nonlinear part of the sensitivity of the active material volume fraction ε_{s,i}. For reference,

$$\frac{\partial {η}_{i} ( t )}{\partial {ɛ}_{s , i}}$$

is also slightly dependent on the particle surface concentration c_{se,i} of lithium. This is because the exchange current density i_{0,i} is weakly correlated with c_{se,i}.

The second term,

$$\frac{\partial {U}_{i}}{\partial {c}_{se , i}} \cdot \frac{\partial {c}_{se , i}}{\partial {ɛ}_{s , i}} ( t ) ,$$

accounts for the impact of ε_{s,i} on the open circuit potential through the surface concentration c_{se,i}.

In the second term,

$$\frac{\partial {U}_{i}}{\partial {c}_{se , i}}$$

may be easily calculated from the open circuit potential function Uᵢ(c_{se,i}) of the battery electrode, which is determined through experiments.

Specifically, the open circuit potential of the battery electrode may be measured for each SOC through an experiment. The SOC may be calculated directly from the accumulated amount of battery current, and c_{se,i} may be calculated from battery current using the first state space model represented by Equation (7)′. When the total accumulated amount of battery current is the same, the SOC and the particle surface concentration c_{se,i} are correlated with each other. Therefore, a function using a particle surface concentration related to the SOC as an input variable and using an open circuit potential as an output may be obtained through curve fitting, and the corresponding function becomes the open circuit potential function Uᵢ(c_{se,i}) of the battery electrode. If the open circuit potential function Uᵢ(c_{se,i}) is given,

$$\frac{\partial {U}_{i}}{\partial {c}_{se , i}}$$

corresponding to the ratio of change in the open circuit potential Uᵢ to the change in the particle surface concentration c_{se,i} may be easily calculated. An example of the open circuit potential function Uᵢ(c_{se,i}) will be disclosed in an experimental example, explained later.

In the second term,

$$\frac{\partial {c}_{se , i}}{\partial {ɛ}_{s , i}}$$

is a sensitivity transfer function, which may be obtained by taking the partial derivative of ε_{s,i} with respect to the Pade approximation equation for c_{se,i} expressed by Equation (7). The following Equation (18) represents the sensitivity transfer function of

$$\frac{\partial {c}_{se , i}}{\partial {ɛ}_{s , i}} .$$

$$\frac{\partial {C}_{se , i} ( s )}{\partial \text{?}} = [ \frac{7 {R}_{s , i}^{4} {s}^{2} + 420 \text{?} {R}_{s , i}^{2} s + 3465 {D}_{s , i}^{2}}{Fs ( {R}_{s , i}^{4} {s}^{2} + 189 \text{?} {R}_{s , i}^{2} s + 3465 \text{?} )} ] \cdot \frac{I ( s )}{{ɛ}_{s , i}^{2} A {δ}_{i}} \\ \text{?} \text{indicates text missing or illegible when filed} \qquad ( 18 )$$

For frequency domain analysis, the Bode plot of the normalized

$$\frac{\partial {c}_{se , i} ( s )}{\partial {ɛ}_{s , i}}$$

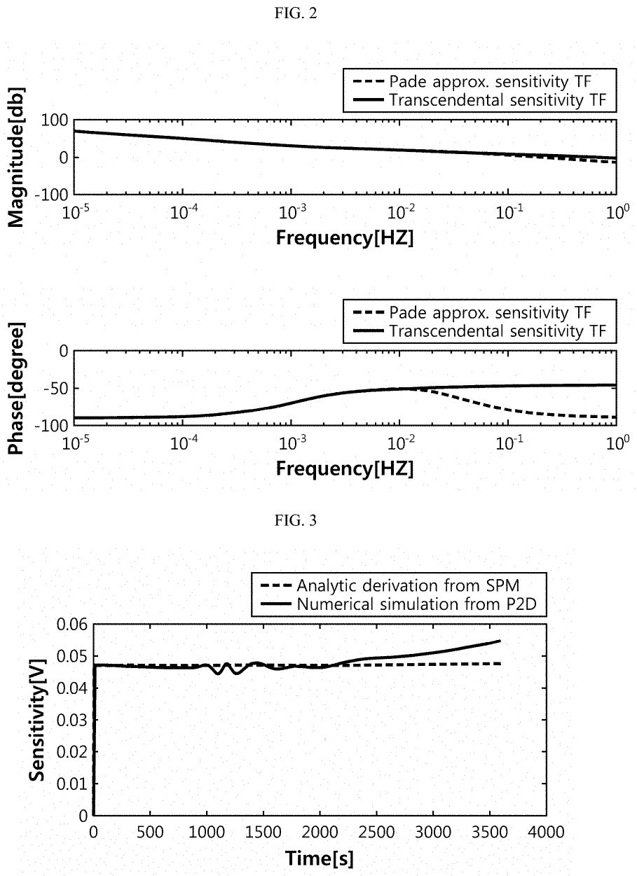

is shown in FIG. 2. The analytic results based on the Pade approximation match the original transcendental transfer function very well at low frequency. The mismatch at high frequency may not be a concern due to the significant attenuation. Instead of remaining constant in low frequency range and rolling off after the break frequency,

$$\frac{\partial {c}_{se , i}}{\partial {ɛ}_{s , i}}$$

shows a monotonic decreasing trend over the whole frequency range. The reason is that

$$\frac{\partial {c}_{se , i}}{\partial {ɛ}_{s , i}} ( s )$$

contains a pole at 0 according to Equation (18). This observation reveals the distinctive dynamic nature between the sensitivity of different parameters and well demonstrates that the sensitivity of different parameters needs to be studied individually.

Since lithium diffusion is a dynamic process, the impact of the active material volume fraction ε_{s,i} on c_{se,i} will change over time even under constant input current.

The sensitivity transition function of Equation (18) may be converted into a second state space model in a canonical format as in Equation (19) to calculate

$$\frac{\partial {c}_{se , i}}{\partial {ɛ}_{s , i}} ( t )$$

under a random current sequence I(t).

$$[ \begin{matrix}{x}_{1}^{′} \\ {x}_{2}^{′} \\ {x}_{3}^{′}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ 1\end{matrix} ] I \\ y = \frac{\partial {c}_{se , i} ( t )}{\partial {ɛ}_{s , i}} = \frac{1}{F {ɛ}_{s , i}^{2} A {δ}_{i} {R}_{s , i}^{4}} [ 3465 {D}_{s , i}^{2} 420 {D}_{s , i} {R}_{s , i}^{2} 7 {R}_{s , i}^{4} ] [ \begin{matrix}{x}_{1} \\ {x}_{2} \\ {x}_{3}\end{matrix} ] \qquad ( 19 )$$

R_{s,i}: radius (m) of electrode particle, ε_{s,i}: volume fraction (no units) of active material with activity in an electrode, A: electrode area (m²): δᵢ: electrode thickness (m), D_{s,i}: solid-phase diffusion coefficient (m²·s⁻¹), F: Faraday constant (C/mol), i: index indicating the type of electrode, I: battery current (A)

Equation (19) shows the effect of the active material volume fraction ε_{s,i} of the electrode on the particle surface concentration c_{se,i} of lithium over time. The current I(t) corresponds to an input of the second state space model and the linear dynamic part

$$\frac{\partial {c}_{se , i}}{\partial {ɛ}_{s , i}} ( t )$$

corresponds to an output y of the second state space model. In an embodiment, the initial conditions of the states x₁, x₂ and x₃ may all be set to 0.

In conclusion, the sensitivity of the active material volume fraction ε_{s,i} to the battery voltage V may be determined analytically by the nonlinear function of the input current I represented by Equation (17),

$$\frac{\partial {U}_{i}}{\partial {c}_{se , i}}$$

calculated from the particle surface concentration c_{se,i} of lithium, which is an output of the first state space model represented by Equation (7)′, and the open circuit potential function Uᵢ(c_{se,i}) of the battery electrode, and

$$\frac{\partial {c}_{se , i}}{\partial {ɛ}_{s , i}} ( t )$$

calculated from the second state space model.

Verification of Analytic Derivation

In this experimental example, the derived analytic results for

$$\frac{\partial V ( t )}{\partial {ɛ}_{s , i}}$$

against the numerical simulation of a full order P2D model in time domain will be verified.

Simulation Set Up

A lithium polymer cell is prepared as a battery. The lithium polymer cell has a capacity of 25.67 Ah and an operation voltage range of 2.75 V to 4.15 V. The verification is performed under two input current profiles, namely constant-current (CC) discharging and current pulsating. Under the CC discharging, the battery initial SOC is set to 100%, and a constant current of 1 c-rate (1C) is applied for an hour, giving a final SOC of 0%. This test is intended to verify the sensitivity over the whole SOC range. The pulsating current profile consists of alternating 1C charging and 1C discharging pulses. Each pulse lasts for 30 seconds and repeats over time. The initial SOC is set to 50%. This test is intended to verify the dynamics of sensitivity under changing current input.

To perform the verification, the sensitivity calculated based on the derived expressions are compared with the numerical simulation of a P2D model. In an embodiment of the present disclosure, the solid-phase diffusion equations along with the boundary conditions thereof are discretized using the Pade approximation. Meanwhile, in the P2D model, the governing equations along with the boundary conditions thereof are discretized in the spatial domain using a central difference method. This discretization results in formation of a system of differential algebraic equations (DAEs) in continuous time. The sensitivity differential equations (SDEs) are obtained by taking the partial derivative of the DAEs to the target variable. The DAEs and SDEs are sequentially simulated using the IDAs integrator from SUNDIALS suite through CasADi's interface, wherein the Jacobians are calculated through CasADi's automatic differentiation.

More detailed simulation method for the P2D model is disclosed in the paper ‘S. Park, D. Kato, Z. Gima, R. Klein, and S. Moura, “Optimal experimental design for parameterization of an electrochemical lithium ion battery model”, Journal of The Electrochemical Society, vol. 165, no. 7, pp. A1309-A1323, 2018.’.

In this verification, the parameter values and the open circuit potential function Uᵢ applied to the embodiment of the present disclosure are as follows. In the first state space model, the initial conditions of x₂ and x₃ are set to 0, and the initial condition of x₁ is set such that the output y of the first state space model is the same as the particle surface concentration c_{se,i} corresponding to the initial value of the SOC. The initial conditions for x₁, x₂ and x₃ of the second state space model are set to 0.

<Parameter>

ε_{s,n}: 0.6, ε_{s,p}: 0.5, ε_{e,n}: 0.3, ε_{e,p}: 0.3, F: 96485.32289, Rₙ: 1.00×10⁻⁵, Rₚ: 1.00×10⁻⁵, R: 8.314472, T: 298.15, αₐ: 1, α_{c}: 1, Lₙ: 1.00×10⁻⁴, Lₚ: 1.00×10⁴, Lₛₑₚ: 2.5×10⁻⁵, L_{c}: Lₙ+Lₚ+Lₛₑₚ, D_{s,n}: 3.90×10⁻¹⁴, D_{s,p}: 1.00×10¹³, R_{f}: 1.00×10⁻³, kₙ: 1.04×10⁻¹⁰, kₚ: 3.11×10⁻¹², c_{s,max,n}: 2.50×10⁴, c_{s,max,p}: 5.12×10⁴, β_{0%,n}: 0.26, β_{100%,n}: 0.6760, β_{0%,p}: 0.936, β_{100%,p}: 0.442, t₊⁰: 0.4, c_{e,p}: 1000, c_{e,n}: 1000, a_{s,p}: 1.50×10⁵, a_{s,n}: 1.80×10⁵, Aₚ: 1, Aₙ: 1, Volₙ: 1.00×10⁻⁴, Volₚ: 1.00×10⁴

<Open Circuit Potential Function of the Positive Electrode and the Negative Electrode>

Uₚ(x)=2.16216+0.07645 tan h(30.834-54.4806x)+2.1581 tan h(52.294-50.294x)−0.14169 tan h(11.0923-19.8543x) 0.2051 tan h(1.4684-5.4888x) 0.2531 tan h((−x+0.56478)/0.1316)−0.02167 tan h ((x−0.525)/0.006) [x=c_{se,p}/c_{s,max,p}, c_{se,p}: particle surface concentration in the positive electrode, c_{s,max,p}: lithium maximum concentration in the positive electrode solid-phase particle]

Uₙ(x)=0.194+1.5exp(−120.0 x)+0.0351 tan h((x−0.286)/0.083)−0.0045 tan h((x−0.849)/0.119)−0.035 tan h((x−0.9233)/0.05)−0.0147 tan h((x−0.5)/0.034)−0.102 tan h((x−0.194)/0.142)−0.022 tan h((x−0.9)/0.0164)−0.011 tan h((x−0.124)/0.0226)+0.0155 tan h((x−0.105)/0.029) [x=c_{se,n}/c_{s,max,n}, c_{se,n}: particle surface concentration in the negative electrode, c_{s,max,n}: lithium maximum concentration in the negative electrode solid-phase particle]

The purpose of this verification is to check whether the analytic results according to the present disclosure match the exact numerical results obtained from computationally intensive simulation.

Verification Results

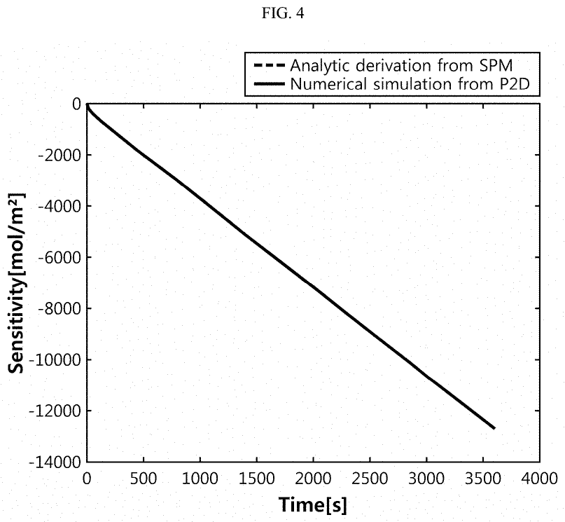

The verification results for the active material volume fraction ε_{s,p} of the positive electrode are presented in FIGS. 3 to 6. Specifically, FIG. 3 shows the verification result of the normalized nonlinear term

$$\frac{\partial η}{\partial {ɛ}_{s , p}} \cdot {ɛ}_{s , p}$$

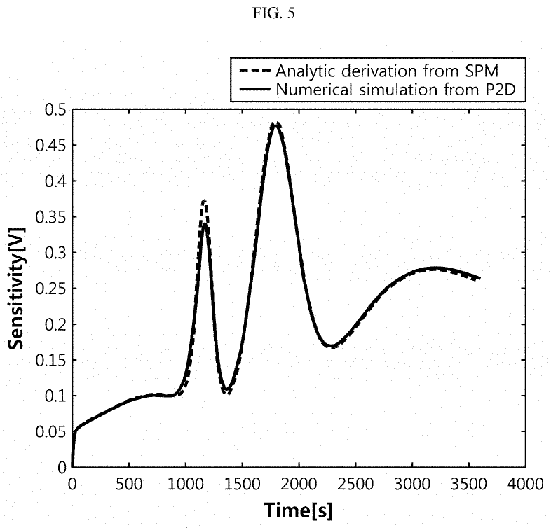

under constant current (CC) discharging. FIG. 4 shows the verification result of the normalized linear dynamic term

$$\frac{\partial {c}_{se}}{\partial {ɛ}_{s , p}} \cdot {ɛ}_{s , p}$$

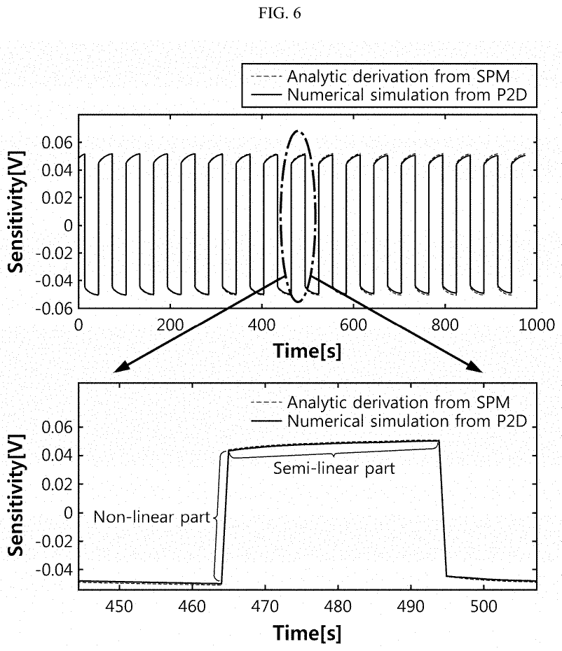

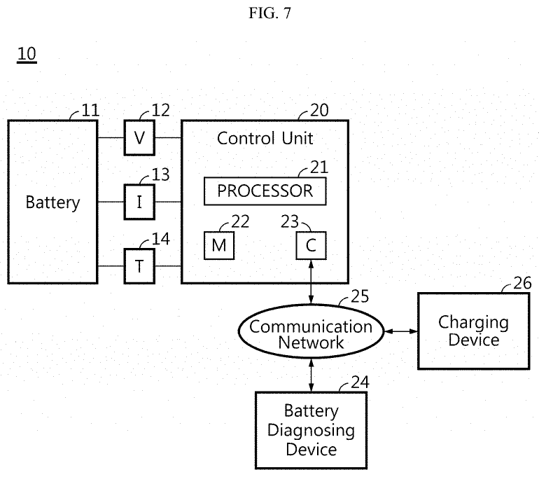

under CC discharging. FIGS. 5 and 6 show the verification result of the normalized overall

$$\frac{\partial V}{\partial {ɛ}_{s , p}} \cdot {ɛ}_{s , p}$$

under CC discharging and pulse current, respectively.

In all these cases, the analytic results (dotted line) match well with the numerical analysis results (solid line) from P2D simulation. Furthermore, several interesting observations can be made. Under CC discharging, as seen in FIG. 4, the magnitude of the normalized

$$\frac{\partial {c}_{se}}{\partial {ɛ}_{s , p}} \cdot {ɛ}_{s , p}$$

keeps increasing over time. This is theoretically predicted by the sensitivity transfer function in Equation (18), which contains a pole at 0, representing the integration of current over time. Meanwhile, the normalized nonlinear term

$$\frac{\partial η}{\partial {ɛ}_{s , p}} \cdot {ɛ}_{s , p}$$

shown in FIG. 3 jumps instantaneously in the beginning and then remain relatively constant, which is also predicted by Equation (17). Therefore, the overall

$$\frac{\partial V}{\partial {ɛ}_{s}}$$

is dominated by the ever-increasing semi-linear dynamic part

$$\frac{\partial {U}_{i}}{\partial {c}_{se , i}} \cdot \frac{\partial {c}_{se , i}}{\partial {ɛ}_{s , i}} ( t )$$

and hence shows the similar profile of the open circuit potential slope as in FIG. 5. As shown in FIG. 6, the instantaneous jumps at periodic switching of current indicates the nonlinear term, and the subsequent transient represents the semi-linear dynamic term. It can be seen that the derived analytic expressions not only enable fast and efficient computation of sensitivity, but also provide theoretic insight and explanation which are unavailable from numerical simulation.

As described above, the analytic derivation for the active material volume fraction ε_{s,i} of the battery electrode is studied. A methodology for derivation is formulated based on the single particle model. Also, the present disclosure demonstrates the analytic results for the active material volume fraction ε_{s,i} of the electrode. The derived analytic expressions are verified through comparison with the numerical simulation of a P2D model, showing satisfactory fidelity.

The derived analytic results could significantly boost the emerging research on data optimization for battery state and parameter estimation. For offline model identification, the analytic expressions have the potential of enabling direct optimization of the input excitation, which is intractable in current practice due to the computational complexity. For real-time state estimation and parameter learning, fast and efficient computation of sensitivity using the analytic expressions facilitates selection of sensitive data from random online data stream. Mining and using sensitive data for estimation could greatly enhance the accuracy and robustness of the results.

Hereinafter, an application embodiment of the analytic derivation with respect to the sensitivity of the battery voltage to the active material volume fraction ε_{s,i} of the battery electrode will be described.

The application embodiment relates to an apparatus and method for mining battery characteristic data having sensitivity to the active material volume fraction ε_{s,i} of the battery electrode.

The application embodiment is to select, mine and collect characteristic data in which the battery voltage shows high sensitivity to the active material volume fraction ε_{s,i} of the electrode from the online data stream for the characteristic data measured through a sensor while the battery is operating.

The mined characteristic data may be used in various ways when diagnosing the state of the battery and controlling the charging of the battery.

As an example, the mined characteristic data may be used to quantitatively evaluate the active material volume fraction c_{s,i} of the battery electrode.

As another example, degradation of the battery may be diagnosed by quantitatively estimating an active material volume fraction ε_{s,i@MOL} of the battery electrode in the MOL (Middle Of Life) state and an active material volume fraction ε_{s,i@BOL} of the battery electrode in the BOL (Beginning Of Life) state by using the mined characteristic data and then comparing the two values relatively.

As still another example, the degree of degradation of the battery estimated from the active material volume fraction ε_{s,i} of the battery electrode may be utilized to optimize the charging power provided to the battery according to the state of the battery. That is, when the active material volume fraction ε_{s,i} does not show a significant difference from the BOL state, the charging power may be increased to the maximum because the active material reacting with lithium ions is sufficient. Meanwhile, when the active material volume fraction ε_{s,i} is much lower than the BOL state, if the charging power is increased, a fatal side reaction such as lithium precipitation may occur, so that the charging power may be sufficiently attenuated compared to the BOL state. Accordingly, charging safety may be improved by adjusting the charging power to match the active material volume fraction ε_{s,i} that may participate in the electrochemical reaction with lithium.

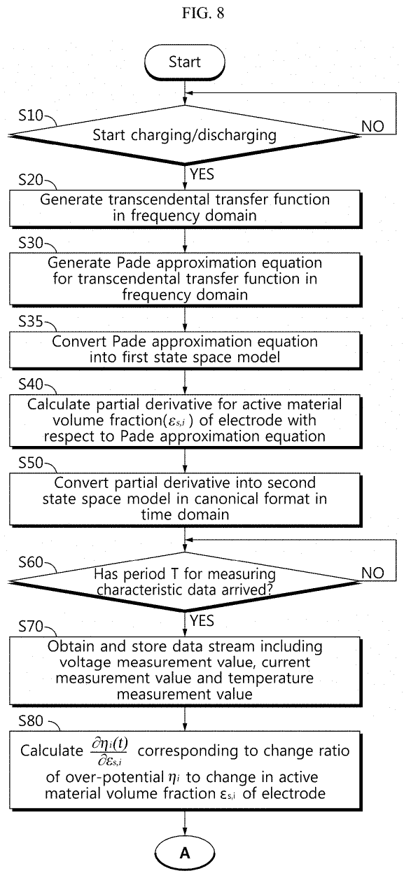

FIG. 7 is a block diagram schematically showing an apparatus for mining battery characteristic data having sensitivity to the active material volume fraction ε_{s,i} of a battery electrode according to an embodiment of the present disclosure.

Referring to FIG. 7, the apparatus 10 for mining battery characteristic data according to the embodiment of the present disclosure is coupled to a battery 11 to select and mine battery characteristic data measured when the voltage of the battery 11 shows high sensitivity to the active material volume fraction ε_{s,i} of the electrode while the battery 11 is operating.

In the present disclosure, mining refers to a data processing process of selecting required data from a plurality of data streams and recording the same in a storage unit 22.

In this embodiment, the battery 11 is a lithium ion battery. The battery 11 includes a positive electrode coated with a positive electrode active material, a negative electrode coated with a negative electrode active material, and a separator for separating the positive electrode and the negative electrode.

The battery 11 includes at least two or more basic units each having a positive electrode/a separator/a negative electrode, and the plurality of basic units may be connected in series and/or in parallel.

The apparatus 10 for mining battery characteristic data includes a voltage measuring unit 12, a current measuring unit 13 and a temperature measuring unit 14. In addition, the apparatus 10 for mining battery characteristic data may include a control unit 20 operatively coupled to the voltage measuring unit 12, the current measuring unit 13 and the temperature measuring unit 14.

The voltage measuring unit 12 measures the voltage applied between the positive electrode and the negative electrode of the battery 11 at regular time intervals (e.g., 1 second) under the control of the control unit 20. The voltage measuring unit 12 may be a voltage sensor and may include a common voltage measuring circuit. The voltage measuring unit 12 outputs a voltage measurement value to the control unit 20 at regular time intervals.

The current measuring unit 13 measures the current of the battery 11 at regular time intervals (e.g., 1 second) under the control of the control unit 20. The current measuring unit 13 may be a current sensor such as a sense resistor or a Hall sensor. The current measuring unit 13 outputs a current measurement value of the battery 11 to the control unit 20 at regular time intervals.

The temperature measuring unit 14 measures the temperature of the battery 11 at regular time intervals (e.g., 1 second) under the control of the control unit 20. The temperature measuring unit 14 may be a temperature sensor such as a thermocouple. The temperature measuring unit 14 outputs a temperature measurement value of the battery 11 to the control unit 20 at regular time intervals.

Preferably, the voltage measurement value, the current measurement value and the temperature measurement value provided to the control unit 20 at regular time intervals constitute a data stream to be mined.

The control unit 20 may include a microprocessor 21. The microprocessor 21 executes the overall control logic for mining the characteristic data of the battery.

Unless otherwise mentioned, various control logics executed by control unit 20 are implemented by programs executed by the microprocessor 21.

The control unit 20 may also include a storage unit 22. As long as the storage unit 22 is a storage medium capable of recording and erasing information, there is no particular limitation on its type.

As an example, the storage unit 22 may be a RAM, a ROM, an EEPROM, a register, or a flash memory.

The storage unit 22 may also be electrically connected to the microprocessor 21 through, for example, a data bus so as to be accessed by the microprocessor 21.

The storage unit 22 also stores and/or updates and/or erases and/or transmit a program including various control logic executed by the microprocessor 21, and/or data generated when control logics are executed and a predefined look-up table or parameters.

The storage unit 22 may be logically divided into two or more parts, and is not limited to be included in the microprocessor 21.

In the present disclosure, the control unit 20 may further selectively include a processor, an application-specific integrated circuit (ASIC), another chipset, a logic circuit, a register, a communication modem, a data processing unit, etc. known in the art to execute various control logics.

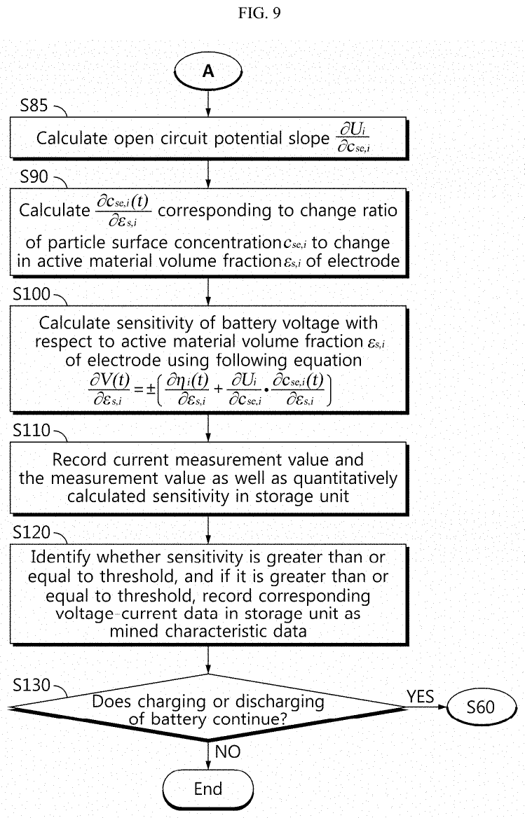

FIGS. 8 and 9 are flowcharts relating to a method for mining battery characteristic data having sensitivity to the active material volume fraction ϵ_{s,i} of a battery electrode according to an embodiment of the present disclosure.

Preferably, the control unit 20 may be configured to execute control logics according to the flowcharts of FIGS. 8 and 9.

First, the control unit 20 determines whether charging or discharging of the battery 11 is started in Step S10. If the determination of Step S10 is YES, Step S20 proceeds, and if the determination of Step S10 is NO, the process progress is held.

In Step 20, the control unit 20 executes a control logic for generating a transcendental transfer function from the battery current (I) to the particle surface concentration (c_{se,i}) of lithium inserted into the electrode in a frequency domain by matching the boundary condition with a solid-phase diffusion sub model of the single particle model (SPM).

Preferably, the control unit 20 may be configured to generate a transcendental transfer function expressed by the following equation in Step S20. The transcendental transfer function may be changed if the chemistry of the battery 11 is changed.

$$\frac{{C}_{se , i}}{I} ( s ) = - \frac{( {e}^{2 {R}_{s , i} \sqrt{s / {D}_{s , i}}} - 1 ) \frac{{R}_{s , i}^{2}}{3 A {δ}_{i} F {ɛ}_{s , i} {D}_{s , i}}}{1 + {R}_{s , i} \sqrt{\frac{s}{{D}_{s , i}}} + {e}^{2 {R}_{s , i} \sqrt{s / {D}_{s , i}}} ( {R}_{s , i} \sqrt{\frac{s}{{D}_{s , i}} - 1} )}$$

C_{se,i}: particle surface concentration (mol·m⁻³), I: battery current (A), R_{s,i}: radius (m) of electrode particle, D_{s,i}: solid-phase diffusion coefficient (m²·s⁻¹) of electrode particle, A: electrode area (m²), δᵢ: electrode thickness (m), ε_{s,i}: volume fraction (no units) of active material with activity in an electrode

Step S30 proceeds after Step S20.

In Step S30, the control unit 20 executes a control logic for generating the Pade approximation equation for the transcendental transfer function in a frequency domain.

Preferably, the control unit 20 may be configured to generate a Pade approximation equation expressed by the following equation in a frequency domain.

$${c}_{se , i} ( s ) \approx - [ \frac{7 {R}_{s , i}^{4} {s}^{2} + 420 {D}_{s , i} {R}_{s , i}^{2} s + 3465 {D}_{s , i}^{2}}{F {ɛ}_{s , i} s ( {R}_{s , i}^{4} {s}^{2} + 189 {D}_{s , i} {R}_{s , i}^{2} s + 3465 {D}_{s , i}^{2} )} ] \cdot \frac{I ( s )}{A {δ}_{i}}$$

c_{se,i}: particle surface concentration (mol·m⁻³), I: battery current (A), R_{s,i}: radius (m) of electrode particle, D_{s,i}: solid-phase diffusion coefficient (m²·s⁻¹) of electrode particle, A: electrode area (m²), δᵢ: electrode thickness (m), ε_{s,i}: volume fraction (no units) of active material with activity in an electrode

Step S35 proceeds after Step S30.

In Step S35, the control unit 20 executes a control logic for converting the Pade approximation equation in the frequency domain into a first state space model in a time domain. The first state space model has a canonical format.

Preferably, the control unit 20 may be configured to generate a first state space model in a canonical format in the time domain as shown in the following equation.

$$[ \begin{matrix}{\dot{x}}_{1} \\ {\dot{x}}_{2} \\ {\dot{x}}_{3}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ - 1\end{matrix} ] I$$

$$y = {c}_{se , i} ( t ) = \frac{1}{F {ɛ}_{s , i} A {δ}_{i} {R}_{s , i}^{4}} [ \begin{matrix}3465 {D}_{s , i}^{2} & 420 {D}_{s , i} {R}_{s , i}^{2} & 7 {R}_{s , i}^{4}\end{matrix} ] [ \begin{matrix}{x}_{1} \\ {x}_{2} \\ {x}_{3}\end{matrix} ]$$

In the first state space model, the input is the battery current I and the output is the particle surface concentration ε_{se,i} of lithium.

Step S40 proceeds after Step S35.

In Step S40, the control unit 20 executes a control logic for calculating a partial derivative equation (PDE) for the active material volume fraction ε_{s,i} of the electrode with respect to the Pade approximation equation generated in the frequency domain.

Preferably, the control unit 20 may be configured to calculate a partial derivative of the Pade approximation equation for the active material volume fraction ε_{s,i} of the electrode as shown in the following equation.

$$\frac{\partial {C}_{se , i} ( s )}{\partial {ɛ}_{s , i}} = [ \frac{7 {R}_{s , i}^{4} {s}^{2} + 420 {D}_{s , i} {R}_{s , i}^{2} s + 3465 {D}_{s , i}^{2}}{Fs ( {R}_{s , i}^{4} {s}^{2} + 189 {D}_{s , i} {R}_{s , i}^{2} s + 3465 {D}_{s , i}^{2} )} ] \cdot \frac{I ( s )}{{ɛ}_{s , i}^{2} A {δ}_{i}}$$

C_{se,i}: particle surface concentration (mol·m⁻³), I: battery current (A), R_{s,i}: radius (m) of electrode particle, D_{s,i}: solid-phase diffusion coefficient (m²·s⁻¹) of electrode particle, A: electrode area (m²), δᵢ: electrode thickness (m), ε_{s,i}: volume fraction (no units) of active material with activity in an electrode

Step S50 proceeds after Step S40.

In Step S50, the control unit 20 may execute a control logic for converting the partial derivative of the Pade approximation equation for the active material volume fraction c_{s,i} of the electrode into a second state space model in a canonical format in a time domain.

Preferably, the control unit 20 may be configured to generate a second state space model in a canonical format as shown in the following equation. In the second state space model, the initial conditions of x₁, x₂ and x₃ may be set to 0, but the present disclosure is not limited thereto.

$$[ \begin{matrix}{\dot{x}}_{1} \\ {\dot{x}}_{2} \\ {\dot{x}}_{3}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ 1\end{matrix} ] I$$

$$y = \frac{\partial {c}_{s e , i} ( t )}{\partial {ɛ}_{s , i}} = \frac{1}{F {ɛ}_{s , i}^{2} A {δ}_{i} {R}_{s , i}^{4}} [ \begin{matrix}3465 {D}_{s , i}^{2} & 420 {D}_{s , i} {R}_{s , i}^{2} & 7 {R}_{s , i}^{4}\end{matrix} ] [ \begin{matrix}{x}_{1} \\ {x}_{2} \\ {x}_{3}\end{matrix} ]$$

R_{s,i}: radius (m) of electrode particle, ε_{s,i}: volume fraction (no units) of active material with activity in an electrode, A: electrode area (m²): δᵢ: electrode thickness (m), D_{s,i}: solid-phase diffusion coefficient (m²·s⁻¹), F: Faraday constant (C·mol⁻¹), i: index indicating the type of electrode, I: battery current (A)

Step S60 proceeds after Step S50.

In Step S60, the control unit 20 determines whether the period T for measuring the characteristic data of the battery 11 has arrived.

If the determination of Step S60 is YES, Step S70 proceeds, and if the determination of Step S60 is NO, the process progress is held.

In Step S70, the control unit 20 executes a control logic for obtaining a data stream including the voltage measurement value, the current measurement value and the temperature measurement value of the battery by using the voltage measuring unit 12, the current measuring unit 13 and the temperature measuring unit 14 and recording the same in the storage unit 22.

Step S80 proceeds after Step S70.

In Step S80, the control unit 20 executes a control logic for calculating

$$\frac{\partial {η}_{i} ( t )}{\partial {ɛ}_{s , i}}$$

corresponding to a change ratio of the over-potential m to the change in the active material volume fraction ε_{s,i} of the electrode by inputting the current measurement value and the temperature measurement value to Equation (17).

Step S85 proceeds after Step S80.

In Step S85, the control unit 20 executes a control logic for inputting the current measurement value to the first state space model to determine the particle surface concentration c_{se,i} of lithium inserted into the electrode and using a predefined open circuit potential function Uᵢ(c_{se,i}) to calculate an open circuit potential slope

$$\frac{\partial {U}_{i}}{\partial {c}_{se , i}}$$

corresponding to the particle surface concentration c_{se,i}.

Step S90 proceeds after Step S85.

In Step S90, the control unit 20 executes a control logic for inputting the current measurement value to the second state space model in a canonical format to calculate a change ratio

$$\frac{\partial {c}_{se , i}}{\partial {ɛ}_{s , i}} ( t )$$

of the particle surface concentration c_{se,i} to the change in the active material volume fraction ε_{s,i} of the electrode.

Step S100 proceeds after Step S90.

In Step S100, the control unit 20 executes a control logic for quantitatively estimating the sensitivity

$$\frac{\partial V ( t )}{\partial {ɛ}_{s , i}}$$

of a battery voltage for the active material volume fraction ε_{s,i} of the electrode from

$$\frac{\partial {η}_{i} ( t )}{\partial {c}_{s , i}}$$

corresponding to the change ratio of the over-potential m to the change in the active material volume fraction ε_{s,i} of the electrode, the open circuit potential slope

$$\frac{\partial {U}_{i}}{\partial {c}_{se , i}}$$

corresponding to the particle surface concentration c_{se,i}, and the change ratio

$$\frac{\partial {c}_{se , i}}{\partial {ɛ}_{s , i}} ( t )$$

of the particle surface concentration to the change in the active material volume fraction ε_{s,i} of the electrode.

Preferably, the control unit 20 may be configured to quantitatively calculate the sensitivity

$$\frac{\partial V ( t )}{\partial {ɛ}_{s , i}}$$

of the battery voltage V with respect to the active material volume fraction ε_{s,i} of the electrode by using the following equation.

$$\frac{\partial V ( t )}{\partial {ɛ}_{s , i}} = \pm ( \frac{\partial {η}_{i} ( t )}{\partial {ɛ}_{s , i}} + \frac{\partial {U}_{i}}{\partial {c}_{se , i}} \cdot \frac{\partial {c}_{se , i} ( t )}{\partial {ɛ}_{s , i}} )$$

Step S110 proceeds after Step S100.

In Step S110, the control unit 20 executes a control logic for recording the current measurement value and the voltage measurement value as well as the quantitatively calculated sensitivity in the storage unit 22.

Step S120 proceeds after Step S110.

In Step S120, the control unit 20 identifies whether the calculated sensitivity is greater than or equal to a threshold, and if it is greater than or equal to the threshold, the control unit 20 records the corresponding voltage-current data in the storage unit 22 as mined characteristic data. In a non-limiting example, the mined characteristic data may further include a temperature measurement value.

Preferably, the control unit 20 may add a flag to the mined characteristic data. The flag is an identifier for distinguishing the mined characteristic data from other characteristic data whose sensitivity is less than the threshold.

Step S130 proceeds after Step S120.

In Step S130, the control unit 20 determines whether charging or discharging of the battery continues.

If the determination of Step S130 is YES, the process returns to Step S60, whereby the aforementioned control logic is repeatedly executed whenever the measurement period T of the characteristic data elapses.

That is, whenever a data stream including the voltage measurement value, the current measurement value and the temperature measurement value is output to the control unit 20 while the battery 11 is being charged or discharged, the control unit 20 may repeat the process of selecting and mining the characteristic data measured when the voltage of the battery 11 shows high sensitivity for the active material volume fraction ε_{s,i} of the electrode in real time. Meanwhile, if the determination of Step S130 is NO, the process of mining battery characteristic data according to the embodiment of the present disclosure is terminated.

Preferably, the periodically repeated mining of battery characteristic data may be performed independently for the active material volume fraction (ε_{s,i}) of the positive electrode or the negative electrode of the battery 11. That is, the analytic sensitivity for the active material volume fraction (ε_{s,p}) of the positive electrode and the analytic sensitivity for the active material volume fraction (ε_{s,n}) of the negative electrode may be calculated independently. In addition, the threshold may be set differently for each of the positive electrode and the negative electrode during the mining of battery characteristic data. In addition, if the analytic sensitivity for the active material volume fraction (ε_{s,p}) of the positive electrode is greater than or equal to the threshold, the corresponding voltage-current data may be classified as the mined characteristic data of the positive electrode and recorded in the storage unit 22. In addition, if the analytic sensitivity for the active material volume fraction (ε_{s,n}) of the negative electrode is greater than or equal to the threshold, the voltage-current data may be classified as the mined characteristic data of the negative electrode and recorded in the storage unit 22.

Meanwhile, the control unit 20 may execute a control logic for estimating the SOC of the battery from the data stream and a control logic for storing the estimated SOC together with the mined characteristic data in executing the control logic of Step S110.

In an example, the control unit 20 may estimate the SOC through an ampere counting method. In another example, the control unit 20 may estimate the SOC by inputting the voltage measurement value, the current measurement value and the temperature measurement value included in the data stream to an extended Kalman filter. The extended Kalman filter is widely known in the art and thus will not be described in detail here.

In addition, the control unit 20 may be configured to further perform a control logic for receiving a request for the transmission of the mined characteristic data from an external battery diagnosing device 24 (FIG. 7) and a control logic for transmitting the mined characteristic data recorded in the storage unit 22 to the battery diagnosing device 24 through a communication network 25 (FIG. 7).

In a non-limiting example, when transmitting the mined characteristic data to the battery diagnosing device 24, the control unit 20 may read information on the sensitivity and/or SOC corresponding to each mined characteristic data from the storage unit 22 and transmit the same together.

The apparatus 10 for mining battery characteristic data according to an embodiment of the present disclosure may further include a communication interface 23 (FIG. 7) for transmitting the mined characteristic data to the outside.

The communication network 25 is not particularly limited as long as it is a commercialized communication network. The communication network 25 includes a wired communication network, a wireless communication network, or a combination thereof. The communication network 25 includes a short-range communication network, a long-range communication network, a wide area communication network, a satellite communication network, or a combination thereof.

Preferably, the battery diagnosing device 24 may store the mined characteristic data as big data in a database and estimate the active material volume fraction ε_{s,i} of the battery electrode by using the mined characteristic data. The model for estimating the active material volume fraction ε_{s,i} may employ any known model in the art without limitation.

The battery diagnosing device 24 may also diagnose the degree of degradation ε_{s,i@MOL}/ε_{s,i@BOL} of the battery by calculating an active material volume fraction ε_{s,i@BOL} of an electrode in the BOL (Beginning Of Life) state and an active material volume fraction ε_{s,i@MOL} of an electrode in the MOL (Middle Of Life) state by using the mined characteristic data collected when the battery 11 is in the BOL state and the mined characteristic data collected when the battery 11 is in the MOL state and relatively comparing ε_{s,i@MOL} over ε_{s,i@BOL}.

The battery diagnosing device 24 may also provide the degree of degradation of the battery calculated from the active material volume fraction ε_{s,i} to a charging device 26 (FIG. 7) of the battery 11 through the communication network 25.

Preferably, the battery diagnosing device 24 may independently calculate the degree of degradation ε_{s,p@MOL}/ε_{s,p@BOL} of the positive electrode and the degree of degradation ε_{s,n@MOL}/ε_{s,n@BOL} of the negative electrode by using the active material volume fraction ε_{s,p} of the positive electrode and the active material volume fraction ε_{s,n} of the negative electrode. In addition, the battery diagnosing device 24 may provide the degree of degradation of the positive electrode and the degree of degradation of the negative electrode to a charging device 26 (FIG. 7) of the battery 11 through the communication network 25.

The charging device 26 of the battery 11 may adaptively adjust the charging power provided to the battery 11 with reference to the degree of degradation of the battery estimated from the active material volume fraction ε_{s,i} of the battery electrode.

Preferably, the charging device 26 of the battery 11 may map the charging power based on a smaller one of the degree of degradation ε_{s,p@MOL}/ε_{s,p@BOL} of the positive electrode and the degree of degradation ε_{s,n@MOL}/ε_{s,n@BOL} of the negative electrode. It is preferable from the viewpoint of stability to adjust the charging power according to an electrode having a relatively small active material volume fraction.

As an example, the charging device 26 of the battery 11 may apply a charging power corresponding to the current degree of degradation of the positive electrode and/or the current degree of degradation of the negative electrode to the battery 11 by referring to a look-up table in which the charging power is predefined according to the degree of degradation of the positive electrode and/or the degree of degradation of the negative electrode.

The charging device 26 of the battery 11 is a charging device of an electric driving mechanism to which the battery 11 is mounted. For example, the charging device 26 of the battery 11 may be a charging station of an electric vehicle to which the battery 11 is mounted.

One or more of the various control logics executed by the control unit 20 may be combined, and the combined control logics may be written in a code system readable by the microprocessor 21 and recorded in a recording medium.

The recording medium is not particularly limited as long as it is accessible by the microprocessor 21. As an example, the recording medium includes at least one selected from the group consisting of a ROM, a RAM, a register, a CD-ROM, a magnetic tape, a hard disk, a floppy disk and an optical data recording device.

The code scheme may be distributed to a networked computer to be stored and executed therein. In addition, functional programs, codes and code segments for implementing the combined control logics may be easily inferred by programmers in the art to which the present disclosure belongs.

The apparatus 10 for mining battery characteristic data according to an embodiment of the present disclosure may be included in a battery management system.

The battery management system controls the overall operation related to charging and discharging of a battery, and is a computing system called a battery management system (BMS) in the art.

The apparatus 10 for mining battery characteristic data according to the present disclosure may be mounted to an electric driving mechanism.

The electric driving mechanism may be an electric power device movable by electricity, such as an electric bicycle, an electric motorcycle, an electric train, an electric ship and an electric plane, or a power tool having a motor, such as an electric drill and an electric grinder.

In the description of the various exemplary embodiments of the present disclosure, it should be understood that the elements referred to as ‘unit’ are distinguished functionally rather than physically. Therefore, each element may be selectively integrated with other elements or each element may be divided into sub-elements for effective implementation control logic(s). However, it is obvious to those skilled in the art that, if functional identity can be acknowledged for the integrated or divided elements, the integrated or divided elements fall within the scope of the present disclosure.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

1. An apparatus for mining battery characteristic data having sensitivity to an active material volume fraction of a battery electrode, comprising:
a storage unit configured to store data;
a voltage measuring unit, a current measuring unit and a temperature measuring unit respectively configured to measure voltage, current, and temperature of a battery; and
a control unit operably coupled to the storage unit as well as the voltage measuring unit, the current measuring unit and the temperature measuring unit,
wherein the control unit is configured to execute control logics to:
generate a Pade approximation equation for a transcendental transfer function from a battery current to a particle surface concentration of lithium inserted into the electrode in a frequency domain;
generate a first state space model for the Pade approximation equation and a second state space model for partial derivative of an active material volume fraction of the electrode with respect to the Pade approximation equation;
obtain a data stream including a voltage measurement value, a current measurement value and a temperature measurement value of the battery;
calculate a change ratio of over-potential to the change in the active material volume fraction by inputting the current measurement value and the temperature measurement value to the partial derivative of the active material volume fraction for an over-potential equation derived from the Butler-Vollmer equation;
input the current measurement value into the first state space model to calculate the particle surface concentration of lithium inserted into the electrode;
input the current measurement value into the second state space model to calculate a change ratio of the particle surface concentration to the change in the active material volume fraction;
calculate an open circuit potential slope corresponding to the calculated particle surface concentration by using a predefined open circuit potential function according to the particle surface concentration;
quantitatively estimate the sensitivity of a battery voltage for the active material volume fraction of the electrode from the change ratio of the over-potential to the change in the active material volume fraction, the open circuit potential slope, and the change ratio of the particle surface concentration to the change in the active material volume fraction; and
select voltage-current data having sensitivity greater than or equal to a threshold and recording the same as mined characteristic data in the storage unit.

2. The apparatus for mining battery characteristic data having sensitivity to an active material volume fraction of a battery electrode according to claim 1,
wherein the control unit is configured to generate the transcendental transfer function expressed by the following equation:
$$\frac{{C}_{se , i}}{I} ( s ) = - \frac{( {e}^{2 {R}_{s , i} \sqrt{s / {D}_{s , i}}} - 1 ) \frac{{R}_{s , i}^{2}}{3 A {δ}_{i} F {ɛ}_{s , i} {D}_{s , i}}}{1 + {R}_{s , i} \sqrt{\frac{s}{{D}_{s , i}}} + {e}^{2 {R}_{s , i} \sqrt{s / {D}_{s , i}}} ( {R}_{s , i} \sqrt{\frac{s}{{D}_{s , i}}} - 1 )}$$
(with C_{se,I} being a particle surface concentration (mol·m⁻³) of lithium inserted into the electrode, I being a battery current (A), R_{s,I} being a radius (m) of electrode particle, D_{s,I} being a solid-phase diffusion coefficient (m²·s⁻¹) of electrode particle, A being an electrode area (m²), δᵢ being an electrode thickness (m), F being the Faraday constant (C·mol⁻¹), ε_{s,I} being a volume fraction (no units) of active material with activity in an electrode, I being an index indicating the type of electrode, s being a variable of Laplace transformation, and e being a natural constant).

3. The apparatus for mining battery characteristic data having sensitivity to an active material volume fraction of a battery electrode according to claim 1,
wherein the control unit is configured to generate the Pade approximation equation expressed by the following equation:
$${c}_{se , i} ( s ) \approx - [ \frac{7 {R}_{s , i}^{4} {s}^{2} + 420 {D}_{s , i} {R}_{s , i}^{2} s + 3465 {D}_{s , i}^{2}}{F {ɛ}_{s , i} s ( {R}_{s , i}^{4} {s}^{2} + 189 {D}_{s , i} {R}_{s , i}^{2} s + 3465 {D}_{s , i}^{2} )} ] \cdot \frac{I ( s )}{A {δ}_{i}}$$
(with c_{se,I} being a particle surface concentration (mol·m⁻³) of lithium inserted into the electrode, I being a battery current (A), R_{s,I} being a radius (m) of electrode particle, D_{s,I} being a solid-phase diffusion coefficient (m²·s⁻¹) of electrode particle, A being an electrode area (m²), δᵢ being an electrode thickness (m), ε_{s,I} being a volume fraction (no units) of active material with activity in an electrode, I being an index indicating the type of electrode, F being the Faraday constant (C·mol⁻¹), and s being a variable of Laplace transformation).

4. The apparatus for mining battery characteristic data having sensitivity to an active material volume fraction of a battery electrode according to claim 1,
wherein the control unit is configured to generate the first state space model expressed by the following equation in a time domain:
$$[ \begin{matrix}{\dot{x}}_{1} \\ {\dot{x}}_{2} \\ {\dot{x}}_{3}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ - 1\end{matrix} ] I$$
$$y = {c}_{s e , i} ( t ) = \frac{1}{F {ɛ}_{s , i} A {δ}_{i} {R}_{s , i}^{4}} [ \begin{matrix}3465 {D}_{s , i}^{2} & 420 {D}_{s , i} {R}_{s , i}^{2} & 7 {R}_{s , i}^{4}\end{matrix} ] [ \begin{matrix}{x}_{1} \\ {x}_{2} \\ {x}_{3}\end{matrix} ]$$
(with c_{se,I} being a particle surface concentration (mol·m⁻³) of lithium inserted into the electrode, R_{s,I} being a radius (m) of electrode particle, ε_{s,I} being a volume fraction (no units) of active material with activity in an electrode, A being an electrode area (m²), δᵢ being an electrode thickness (m), D_{s,I} being a solid-phase diffusion coefficient (m²·s⁻¹), F being the Faraday constant (C·mol⁻¹), I being an index indicating the type of electrode, and I being a battery current (A)).

5. The apparatus for mining battery characteristic data having sensitivity to an active material volume fraction of a battery electrode according to claim 1,
wherein the control unit is configured to generate the second state space model expressed by the following equation in a time domain:
$$[ \begin{matrix}{\dot{x}}_{1} \\ {\dot{x}}_{2} \\ {\dot{x}}_{3}\end{matrix} ] = [ \begin{matrix}0 & 1 & 0 \\ 0 & 0 & 1 \\ 0 & \frac{- 3465 {D}_{s , i}^{2}}{{R}_{s , i}^{4}} & \frac{- 189 {D}_{s , i}}{{R}_{s , i}^{2}}\end{matrix} ] [ \begin{matrix}{x}_{1} \\ {x}_{2} \\ {x}_{3}\end{matrix} ] + [ \begin{matrix}0 \\ 0 \\ 1\end{matrix} ] I$$
$$y = \frac{\partial {c}_{s e , i} ( t )}{\partial {ɛ}_{s , i}} = \frac{1}{F {ɛ}_{s , i}^{2} A {δ}_{i} {R}_{s , i}^{4}} [ \begin{matrix}3465 {D}_{s , i}^{2} & 420 {D}_{s , i} {R}_{s , i}^{2} & 7 {R}_{s , i}^{4}\end{matrix} ] [ \begin{matrix}{x}_{1} \\ {x}_{2} \\ {x}_{3}\end{matrix} ]$$
(with c_{se,I} being a particle surface concentration (mol·m⁻³) of lithium inserted into the electrode, R_{s,I} being a radius (m) of electrode particle, ε_{s,I} being a volume fraction (no units) of active material with activity in an electrode, A being an electrode area (m²), δᵢ being an electrode thickness (m), D_{s,I} being a solid-phase diffusion coefficient (m²·s⁻¹), F being the Faraday constant (C·mol⁻¹), I being an index indicating the type of electrode, and I being a battery current (A)).

6. The apparatus for mining battery characteristic data having sensitivity to an active material volume fraction of a battery electrode according to claim 1,
wherein the control unit is configured to quantitatively calculate the sensitivity of the battery voltage with respect to the active material volume fraction of the electrode using an approximate equation expressed by the following equation:
$$\frac{\partial V ( t )}{\partial {ɛ}_{s , i}} = \pm ( \frac{\partial {η}_{i} ( t )}{\partial {ɛ}_{s , i}} + \frac{\partial {U}_{i}}{\partial {c}_{se , i}} \cdot \frac{\partial {c}_{se , i} ( t )}{\partial {ɛ}_{s , i}} )$$
(with V being a battery voltage (Volt), c_{se,I} being a particle surface concentration (mol·m⁻³) of lithium inserted into the electrode, ε_{s,I} being a volume fraction (no units) of active material with activity in an electrode, Uᵢ being an open circuit potential function of the electrode, ηᵢ being an over-potential (V) of the electrode, i being an index indicating the type of electrode).

7. The apparatus for mining battery characteristic data having sensitivity to an active material volume fraction of a battery electrode according to claim 1,
wherein the control unit is configured to estimate a SOC of the battery from the data stream and store the mined characteristic data and the SOC together in the storage unit.

8. The apparatus for mining battery characteristic data having sensitivity to an active material volume fraction of a battery electrode according to claim 1,
wherein the control unit is further configured to:
receive a request for the transmission of mined characteristic data from a battery diagnosing device; and
read the mined characteristic data from the storage unit and transmit the same to the battery diagnosing device.

9. The apparatus for mining battery characteristic data having sensitivity to an active material volume fraction of a battery electrode according to claim 8,
wherein the battery diagnosing device is a device for estimating an active material volume fraction of the battery electrode by using the mined characteristic data.

10. The apparatus for mining battery characteristic data having sensitivity to an active material volume fraction of a battery electrode according to claim 1,
wherein the control unit is configured to repeatedly execute the control logics to calculate the change ratio, input the current measurement value, input the current measurement value, calculate the open circuit potential slope, quantitatively estimate the sensitivity of the battery voltage, and select the voltage-current data whenever a data stream is obtained through the control logic to obtain the data stream.

11. A battery management system, comprising the apparatus for mining battery characteristic data having sensitivity to an active material volume fraction of a battery electrode according to claim 1.

12. An electric driving mechanism, comprising the apparatus for mining battery characteristic data having sensitivity to an active material volume fraction of a battery electrode according to claim 1.

13. A method for mining battery characteristic data having sensitivity to an active material volume fraction of a battery electrode, comprising:
generating a Pade approximation equation for a transcendental transfer function from a battery current to a particle surface concentration of lithium inserted into the electrode in a frequency domain;
generating a first state space model for the Pade approximation equation and a second state space model for partial derivative of an active material volume fraction of the electrode with respect to the Pade approximation equation;
obtaining a data stream including a voltage measurement value, a current measurement value and a temperature measurement value of the battery;
calculating a change ratio of over-potential to the change in the active material volume fraction by inputting the current measurement value and the temperature measurement value to the partial derivative of the active material volume fraction for an over-potential equation derived from the Butler-Vollmer equation;
inputting the current measurement value into the first state space model to calculate the particle surface concentration of lithium inserted into the electrode;
inputting the current measurement value into the second state space model to calculate a change ratio of the particle surface concentration to the change in the active material volume fraction;
calculating an open circuit potential slope corresponding to the calculated particle surface concentration using a predefined open circuit potential function according to the particle surface concentration;
quantitatively estimating the sensitivity of a battery voltage for the active material volume fraction of the electrode from the change ratio of the over-potential to the change in the active material volume fraction, the open circuit potential slope, and the change ratio of the particle surface concentration to the change in the active material volume fraction; and
selecting voltage-current data having sensitivity greater than or equal to a threshold and recording the same as mined characteristic data in a storage unit.

14. The method for mining battery characteristic data having sensitivity to an active material volume fraction of a battery electrode according to claim 13, further comprising:
estimating a SOC of the battery from the data stream,
wherein the step of selecting the voltage-current data includes storing the mined characteristic data and the SOC together in the storage unit.

15. The method for mining battery characteristic data having sensitivity to an active material volume fraction of a battery electrode according to claim 13, further comprising:
receiving a request for the transmission of mined characteristic data from a battery diagnosing device; and
transmitting information recorded as the mined characteristic data to the battery diagnosing device.
